(19) United States
(12) Patent Application Publication
(10) Pub. No.: US 2015/0069911 A1
(43) Pub. Date: Mar. 12, 2015

(54) HAND-HELD DEVICE AND METHOD OF PLASMA TREATMENT OF A WORKPIECE WITH THE HAND-HELD DEVICE

(71) Applicant: Reinhausen Plasma GmbH, Regensburg (DE)

(72) Inventors: Stefan Nettesheim, Berlin (DE); Klaus Forster, Bad Abbach (DE); Arif Demirci, Tegernheim (DE)

(21) Appl. No.: 14/480,852

(22) Filed: Sep. 9, 2014

(30) Foreign Application Priority Data
Sep. 10, 2013 (DE) 102013109887.8

(51) Int. Cl. H01J 37/244; H01J 37/24; H01J 37/32; H01J 37/22; G01J 5/02; G01F 1/00

(52) U.S. Cl. CPC H01J 37/244; G01J 5/02; G01F 1/00; H01J 37/32357; H01J 37/226; H01J 37/32908; H01J 37/32449; H01J 37/241; H05H 2001/4645
USPC 315/111.21

(57) ABSTRACT

A hand-held device and a method for plasma treatment of workpieces. The hand-held device comprises a housing for receiving a plasma source supplied with a gas stream from a gas supply unit. Further, an electrode unit is arranged in the plasma source and connected via an electrical line with a voltage source so that a plasma stream can be produced. The plasma stream can be directed through a nozzle of the housing onto a workpiece. The hand-held device comprises a sensor system for the collection of operating parameters which includes at least one operator sensor device for collecting a position of an operator relative to the plasma source and at least one pressure sensor for the collection of a pressure in the gas supply unit. Means of the hand-held device is communicatively connected with the sensor system for detecting the collected operating parameter via control data lines.

### CROSS-REFERENCE TO RELATED APPLICATIONS

This application claims priority from German Patent Application No. 10 2013 109 887.8, filed Sep. 10, 2013, which application is incorporated herein by reference in its entirety.

### FIELD OF THE INVENTION

The present invention relates to a hand-held device for the plasma treatment of workpieces. Additionally the invention relates to a method for plasma treatment of workpieces with a hand-held device.

### BACKGROUND OF THE INVENTION

German Patent Application No. DE102009038563 (Droste) discloses a device with a current collector in a plasma jet for transferring electrical current. An end of the current collector is electrically and conductively connected with a grounded housing of a plasma generator. A matching resistor, a current measuring device and a measuring amplifier are connected between ends of the current collector. The measuring amplifier is connected with an output unit such that measuring signal is displayed by the output unit, where the measuring signal allows direct inference on the produced plasma jet. An independent claim is also included for a method for directly monitoring a plasma jet.

European Patent No. EP1270095 (Zisch) discloses a method which involves detecting the temperature T of the surface being treated. The temperature of the surface rises with the duration of the pre-treatment process, and the surface temperature is used to assess the quality of the pre-treatment. The quality is error-free if the temperature has exceeded a minimum value (Tmin) and remains below a maximum value (Tmax). The surface temperature can be detected with an infrared sensor. The temperature may be an input variable for a control loop. Controlled variables are the intensity of the plasma jet or its positioning relative to the surface. This intensity can be varied both by the magnitude of the applied voltage and by the strength of the flow of gas.

International Patent Application No. WO 2011/055368 (Lam) shows a compact medical device for tissue welding. The hand-held plasma heads are configured for deep cuts and long cuts. Plasma created from a gas such as helium is then applied to the bio-compatible liquid to solidify it and seal the wound. A housing of such hand-held device includes a battery as a power source of an radio frequency (RF) ignition device, a gas subsystem of a high-pressure gas tank, a pressure regulator and a gas flow controller, and a tubular tip, in which the plasma is generated. The tip may be connected via a flexible hose with the remainder of the housing. Through an opening in the top the plasma can emerge as a focused beam. The ignition electrodes are preferably configured bipolar. The patient's tissue can be grounded against the RF igniter. The housing may carry a user interface. The operating element is used for controlling the RF and ignition of the gas or the subsystem receiving a plasma-feedback signal. The plasma temperature is below 70° C. and can be maintained by a control loop. Input variables to a control unit for carrying out this control loop are the RF power, RF impedance spectrum of the plasma, or the temperature of the tissue. The RF power and the gas flow are to be regulated. The plasma jet can be supplied from a reservoir with biocompatible liquids.

United States Patent Application Publication No. 2012/244290 (Mullin et al.) discloses an apparatus for depositing a coating on one or more parts. The apparatus has a chamber and a part holder for carrying the part or parts. A bias voltage source is coupled to the part or parts to apply a bias voltage to the parts or parts. A plurality of temperature sensors and a plurality of leads are provided, which are used to pass out of the temperature sensors out from the chamber. A temperature monitoring system has a temperature data processor. At least one fiber optic link couples the temperature data processor to the temperature sensors so as to electrically isolate the temperature data processor from the bias voltage.

United States Patent Application Publication No. 2012/228271 (Anzengruber et al.) relates to a hose assembly which comprises a plurality of lines for supplying a welding torch with operating media, such as welding current, welding wire, protective gas and/or control signals. At least one coolant line is provided for feeding cooling medium of a coolant source to the welding torch and having at least one coupling element for detachably connecting to a welding unit or to a welding torch if necessary. A further coupling element is needed for the at least one coolant line which is integrated in the coupling element. The coupling and decoupling direction of the further coupling element are orientated transverse to the longitudinal axis of the hose assembly. For cooling purposes a bulky and expensive cooling fluid system is integrated, which makes the device bulky for mobile use.

### BRIEF SUMMARY OF THE INVENTION

A hand-held device and a method for plasma treatment of workpieces. The hand-held device comprises a housing for receiving a plasma source. The plasma source is supplied with a gas stream from a gas supply unit. Further, an electrode unit is arranged in the plasma source and connected via an electrical line with a voltage source so that a plasma stream can be produced. The plasma stream can be directed through a nozzle of the housing onto a workpiece. Further, the hand-held device comprises a sensor system for the collection of operating parameters. The sensor system includes at least one operator sensor device for collecting a position of an operator relative to the plasma source and at least one pressure sensor for the collection of a pressure in the gas supply unit. Means of the hand-held device is communicatively connected with the sensor system for detecting the collected operating parameter via control data lines. Similarly, at least the voltage source is connected with the means and controllably by the means.

It is an object of the present invention to provide a versatile, simply constructed and durable hand-held device with which even an unskilled operator can carry out in a simple, process oriented and reliable manner, the plasma treatment of a workpiece.

This object is achieved by a hand-held device for the plasma treatment of workpieces comprising: a housing for containing a plasma source; a gas supply unit for supplying a gas stream to the plasma source; a voltage source, being connected via at least one electrical lead with an electrode unit of the plasma source for generating a plasma stream; an outlet nozzle of the housing from which the plasma stream can be directed to a workpiece; a sensor system for the collection of operating parameters, wherein the sensor system has at least one operator sensor device with a left hand sensor and a right hand sensor to levy a position of a right hand and a left hand of an operator on the housing, and thereby a position of the operator is detectable with respect to the plasma source, and at least one pressure sensor for imposing a pressure in the gas supply unit; and a means which is communicatively coupled to the sensor system for synchronized detection of the collected operating parameters and to at least to the voltage source for its control via control data lines.

It is a further object of the invention to provide flexible useable method, with which even an unskilled operator can carry out a plasma treatment of a workpiece in a simple, process oriented and reliable manner.

This object is achieved by a method for the plasma treatment of workpieces comprising: generating with a plasma source of a hand-held device a plasma stream for the plasma treatment; directing the generated plasma stream to a workpiece; collecting with a sensor system at least two operating parameters, wherein with at least at least one operator sensor device with a left hand sensor and a right hand sensor detect a position of an operator relative to the plasma source, and with at least one pressure sensor of the sensor system, a pressure in a gas supply unit of the plasma source is detected; synchronizing the collected operating parameters with a means; and generating control signals by the means, which are based on the collected operating parameters for unblocking and/or controlling at least a voltage source of the plasma source.

The invention relates to a hand-held device for the plasma treatment of workpieces. On workpieces surface areas for soldering or gluing can be selectively chosen, for example to be disinfected, to be activated, to be coated or to be ablated by plasma treatment. Rather than a workpiece, however, also a human being or animal can be treated in a wound area with a cold plasma suitable medical (for example, below 70° C.). In particular, the device can be designed compact and lightweight that it can be guided by a typical user or operator with one or two hands. The hand-held device is particularly intended for guidance by a human operator. Alternatively, it can be a robot with a movable robot arm.

The hand-held device comprises a housing for receiving a plasma source, a gas supply unit for supplying a gas stream to the plasma source, and a voltage source which is connected via an electrical line to an electrode unit of the plasma source for the generation of a plasma stream. The housing has formed a discharge nozzle, from which the plasma stream can be directed to one or several work pieces. The plasma stream preferably consists of from atmospheric and/or cold plasma.

Furthermore, the hand-held device includes a sensor system for acquisition of operating parameters. The sensor system comprises at least one operator sensor to detect an operator's position relative to the plasma source and at least one pressure sensor to detect a static and/or dynamic pressure or partial pressure in the gas supply unit and/or in the plasma source. In addition, the hand-held device comprises a means, such as a controller, communicatively coupled to the sensor system for synchronized recording of the detected operating parameters collected and which is at least connected to the voltage source for controlling purposes via data lines. The means, the sensor system, the voltage source and where applicable the gas supply unit form a control loop for situational plasma treatment with defined plasma parameters.

According to the invention, the sensor system of the hand-held device additionally comprises one or a combination of several additional sensors. These additional sensors include, for example, at least one flow sensor for collecting a flow rate of the gas stream through the plasma source. The flow sensor is arranged in the plasma source or in the gas supply unit. Further, the sensor system has at least one temperature sensor for determining a temperature of the plasma source. The temperature sensor is arranged in or at the plasma source. Also conceivable is a temperature sensor for measuring a surface temperature of at least an area on the workpiece to be plasma-treated. The sensor system may comprise at least one camera for capturing at least a portion of the workpiece. Similarly, at least one kinematic sensor can be included to collect at least one kinematic value of the hand-held device relative to the workpiece. Kinematic values are positions, translational or rotational velocities and accelerations with respect to one, two or three spatial dimensions and axis in space, respectively. The angle detection is of importance, because the uniformity and surface dose of the plasma treatment depend on the angle at which the plasma jet is directed onto the workpiece. In the hand-held device according to the invention an acceleration sensor may substitute a speed sensor or a position sensor. The acceleration sensor detects the operating parameters, like the acceleration, in a time-resolved manner and numerically integrates the operating parameters, like speed or position, with respect to a starting position. The means can preferably be designed as a computer or microcontroller.

The means or the sensor system can be particularly designed to carry out each one target-adjustment for each operating parameter collected by the sensor system.

The hand-held device may also comprise a targeting device, which is used to mark a location, and/or an area on the workpiece to which the plasma stream is directed. In the simplest case, the target device may be an attachment to the plasma outlet. The length of the attachment thus determines the working distance of the nozzle to workpiece.

In a further embodiment, the target device may include at least one projector, with which at least a light signal is projected onto the workpiece, preferably to the location or the region of the workpiece to which the plasma beam acts.

In a particular embodiment, the light signals of the at least one projector can be modulated in time, color and/or with respect to their form. For example, light signals may be green, as long as one or more operating parameters are within a particular target range. In case an operating parameter approaches or exceeds the target range within a particular tolerance range, the light signal can switch to orange for example. Exceeds an operating parameter the tolerance range, the light signal can switch to red for example. In this case, the projector would be configured as a light-emitting diode array or laser diode array. Instead of a color identification the crossing tolerance range can also be indicated by a characteristic flashing light signal. This has, compared to the color identification, the advantage is that only one type of light emitting diode is required per projector. Furthermore, the wavelength of the light signal can be chosen so that it is clearly visible on the workpiece.

Additionally, the hand-held device can also be provided on the at least one operator display. By means of such an operator display optical, acoustical and/or vibrational notes to the operator can be output with respect to the operating state of the hand-held device. The operating state is determined according to the invention mainly by exceeding or falling short of the upper and lower threshold values by operating parameters. These operating parameters include, for example, the working distance or a speed of the plasma outlet nozzle with respect to the surface of the workpiece, the angular orientation of the hand-held device relative to a local surface normal of the workpiece, the temperature at the plasma outlet or on the workpiece and of the static or dynamic pressure in the plasma source.

The Exceeding and/or falling below thresholds can be highlighted, for example, with various and in particular, characteristic warning sounds. The operator note can be a vibration. The vibration can be generated by a vibrator which is mechanically coupled to the housing or an operating element of the hand-held device.

The operator sensor device can be designed as an operating element for input of control signals by the operator. For example, such an operator sensing device includes for example mechanical pressure controls or control dials or capacitive controls. For example, a first control element regulates the gas stream and a second control element adjusts the voltage of the voltage source. By means of control element, such as a capacitive touchpad, one or more preset plasma parameters or plasma powers can be selected manually. These plasma parameters are the electron and ion temperatures, the degree of ionization and pressure and flow conditions in the plasma stream.

The operator sensor device can be designed especially as a first-hand sensor to survey the position of a right hand, and as a second hand sensor to survey the position of the left hand of the operator on the housing. Preferably, the first and second hand sensor are arranged on the housing and spaced from each other that they cannot be operated with an ordinary human hand (about 15-30 cm long). According to a particular embodiment of the inventive hand-held device the voltage and/or the gas flow are unblocked only as long as signals are detects from the first and second hand sensor. By the clear assignment of the position of operator's both hands it is ensured that none of his hands gets into the plasma stream and is injured.

The means may, in particular, be communicatively connected with a database for storing operating parameters and/or, derived and/or on the operator related metadata. From the operating parameters, for example a machining profile yields and it is derivable therefrom, respectively. Operator related metadata are for example, an identifier of the operator or the workpiece to be machined by him, the period of processing and if applicable environmental influences, like outside temperature or humidity. The communicative connection can be wired or wireless or it can be a portable storage medium such as an SD card or a USB flash drive. By the linkage of process profiles derived from operating parameters and user-related metadata as well as the monitoring and control of the plasma treatment a Manufacturing Execution System (MES) is implemented with the hand-held device. For example, an electronic sig-nature is logged, when and who has treated a particular workpiece along a trajectory and with which plasma parameters. Many work sharing manufacturing processes with numerous consecutive process steps require such electronic signatures for process safety and quality management.

The means may be communicatively connected via a data line to the gas supply unit for controlling the gas stream. Thus, the plasma parameters can be adjusted, wherein the means control the gas flow and the voltage in a synchronized manner. The gas supply unit is implemented, for example, as an adjustable blower and/or a pressurized gas-bottle with a controllable valve. Preferably, the supply unit is integrated in the housing of the hand-held device or mounted on the housing. In case the voltage source is fed from a battery arranged in or on the housing, the hand-held device is not provided with a cable or hose. The hand-held device is portable and flexible deployable. Alternatively, a connection valve may be provided on the housing for a pressurized gas line. From the pressurized gas line or from the pressurized gas bottle, the hand-held device is supplied with various gases, such as compressed air, inert gases (like argon or nitrogen) or reactive gases. Further, a liquid or powder additive is added from a reservoir to the gas stream through a mixing device, and if necessary, it is activated by plasma. The additive is for example be a flux material for a subsequent soldering process, a reducing or oxidizing agent, a medically active substance or a coating material.

The invention further relates to a method for plasma treatment of a workpiece. In order to carry out the plasma treatment with a plasma source, like a hand-held device, a plasma stream is generated. The plasma stream thus formed is directed by an operator of the hand-held device to a workpiece. At least two operational parameters are obtained with a sensor system during the plasma treatment. At least a position of the operator relative to the plasma source is obtained with an operator sensor device and a pressure in a gas supply of the plasma source is obtained with at least one pressure sensor of the sensor system. In this way, collected operating parameters are transmitted in a synchronized manner to a means. The synchronization allows the temporal correlation of operating parameters. Control signals are generated by the means which are used to deblock and/or control a voltage source of the plasma source and if necessary of the gas supply unit.

At least an additional operating parameter can be obtained with the sensor system. One of these additional operating parameters is for example, at least one flow rate of the gas stream, which is obtained by means of at least one flow sensor arranged in the plasma source or the supply unit. Also, at least a temperature of the plasma source can be detected by means of at least one temperature sensor arranged in or at the plasma source. It is also conceivable to detect the temperature of a portion the plasma-treated workpiece, with an infrared sensor in order to detect overheating of the workpiece, or to avoid it. Furthermore, a visual representation of at least a portion of the workpiece is generated by a camera of the hand-held device. In this case, the device is preferably designed to run image recognition processes, so that certain structures can be identified or localized on the workpiece.

There is also a “teach-in” method conceivable wherein a reference image of a structure is stored first in the hand-held device. This structure is then searched and evaluated on the workpieces by the camera of the hand-held device. The machining process is triggered with corresponding similarity only. Such structures can be, for example, markers, electronic components on a circuit board or sutures.

The means can, based on the location of the structures, locate one area to be worked on with the hand-held device. Shape and target-position of the structures and area to be worked on are programmed in advance into the means. In particular, at least one kinematic operating parameters of the hand-held device is detected relative to the workpiece by at least one kinematic sensor which arranged on the hand-held device. The subject to regulation by the means is, for example, to keep the plasma parameters constant. In case kinematic sensors are part of the control loop, the means can also maintain plasma power per area constant in order to support an operator in a for a achieving a homogeneous plasma treatment.

With suitably adjusted depth of field of the camera, it is also possible to determine from the image data the correct working distance. If in addition an image recognition method is applied to the image data, complete spatial information can be determined for the plasma processing to be carried out or continuously monitored. The set depth of field can be used that the hand-held device is during the processing of the workpiece in the desired working distance defined by the depth of field.

According to the invention a target-actual comparison can be performed by-the determined operating parameters. The device generates control signals in case the associated target-actual comparison of the appropriate operating parameters exceed for more than a respective time interval a respective minimum or maximum threshold or stays within a respective desired interval. A desired interval is defined by a respective upper and lower threshold.

In particular, operator instructions are displayed by means of an operator display of the hand-held device to the operator. The operator instructions refer for example to the operational readiness of the hand-held device, on at least one determined operating parameter and/or to the exceeding or falling below the upper and lower thresholds by at least one of the collected operating parameters, respectively.

Furthermore, a location and/or an area can be marked on the workpiece by means of a target device on the hand-held device to which the plasma stream is directed. The target device is in the simplest case, a mechanical attachment on an outlet nozzle for the plasma jet. Preferably, the target device includes at least one projector. Each projector is able to project at least one light signal onto the workpiece.

In particular, a desired trajectory can be defined over the workpiece by time-dependent kinematic reference intervals of operating parameters. A start point or local reference point can be sensed by the operator, by the camera or by a location sensor on the workpiece. The operator guides the hand-held device on an actual trajectory along the nominal trajectory over the workpiece. Deviations of the plasma treatment along this trajectory, for example with respect to the plasma parameters, the speed of the hand-held device, the area dose of the plasma acting upon the workpiece, etc., are confirmed and or logged to user by the device. The threshold values can be modulated locally with respect to the area dose of the plasma or the maximum surface temperature of the workpiece with appropriate programming in order to protect, for example, a heat sensitive component on the trajectory.

Should the situation arise, the reference trajectory is not or not easily discernible on the workpiece for the human operator. Therefore, the invention provides that the target device projects the target trajectory at least partially on the workpiece. The tagged section marks for example the area, the feed direction or the feed speed with which the operator has to carry the hand-held device. Thus, even a not skilled operator can run a complex plasma treatment of a workpiece.

In order to achieve increased operating and process safety the inventive method preferably provides that the means outputs control signals to the voltage source only as long as no determined operating parameter is more than a respective time interval, outside of each target interval, or falls below, respectively, exceeds a respective minimum or maximum threshold value.

According to the invention the means may also generate control signals for a gas supply unit of the plasma source. It can also regulate the voltage source and the gas supply unit as a function of the operating parameters prevailing in each of the gas supply unit and the − voltage source.

By means of an internal clock, the means controls the voltage source and the gas supply unit in a time controlled manner such that the gas stream is flowing through the plasma source during a flow period before release of the power source and/or during a stopping time after switching off the voltage source.

The operating parameters and/or derived operating parameters and/or user related metadata are communicatively coupled to a device to the database. Out of it an electronic signature can be generated for each plasma-treated workpiece and its charge, respectively.

An essential idea of the invention is based on the serial connection (AND operation) of different sensors in a hand-held device for plasma treatment. The sensors detect operating parameters which are relevant to the occupational and operational safety. In case the operating parameters deviate from predetermined threshold values, the voltage supply of the plasma stream is disabled or enabled by the means of the hand-held device. In the correlation of different operational parameters additional information is included about the plasma treatment.

This means links measured operating parameters, like gas pressure and gas flow, the relative position of the outlet nozzle to the workpiece and/or to the operator and the position of one or both hands of the operator on the hand-held device. According to a fixed timing the means enables or disables the gas supply unit and/or the voltage source.

A typical sequence requires, determining the hand position(s) of the operator, then releasing the ramp-up of the gas supply unit, then determining the pressure and flow of the gas stream and the correct position of the outlet nozzle to the processing location. After a time delay of typically 1 second, after powering up of the gas supply unit, the release of the voltage source is carried out. In blocking of the voltage source, a follower of the gas supply unit is typically 5 seconds is carried out for cooling and electrostatic charge balance in the plasma source.

This security mechanism not only increases the work and process safety, but also protects the plasma source and thus contributes to a longer life of the hand-held device. An increased work safety allows additionally to increase the hitherto little, for security reasons limited, power of hand-held plasma sources. This allows production processes to be more efficient or new usage areas for hand-held plasma sources are developed. Furthermore, the inventive means can accept the setting and regulation of the plasma parameters. By this partial automation also an unskilled operator can execute a fundamentally complex plasma treatment in a simple way. Especially, in divisional labor manufacturing processes the electronic documentation wins preferably of each process step is steadily increasing. The hand-held device according to the invention can accommodate this requirement, wherein relevant operating parameters and/or related metadata are logged in the means or in an affiliated database. In this way, sources of error in the overall process are comprehensible and easily to remove. Some markets remain closed without such process logs or electronic signatures. In particular, a partially automated hand-held device according to the invention can monitor the correct execution of the plasma treatment and provides the operator with a direct feedback and assistance.

### BRIEF DESCRIPTION OF THE DRAWINGS

The nature and mode of operation of the present invention will now be more fully described in the following detailed description of the invention taken with the accompanying drawing figures, in which:

FIG. 1 is a schematic view of an embodiment of a hand-held device of the invention for plasma treatment of workpieces;

FIG. 2 is a schematic side view of another embodiment of the inventive hand-held device;

FIG. 3 is a schematic view of an embodiment of a housing of the inventive hand-held device;

FIG. 4A is a schematic view of a further embodiment of the housing of the inventive hand-held device;

FIG. 4B is a schematic view of the embodiment of the housing of the hand-held device according to the invention of FIG. 4A from a different angle;

FIG. 5 is a schematic view of another embodiment of the housing of the inventive hand-held device;

FIG. 6A is a schematic view of a targeting device of the hand-held device according to the invention for marking an area on a workpiece to be plasma treated;

FIG. 6B is a schematic plan view of the targeting device of the hand-held device according to FIG. 6A wherein the with workpiece is marked with operator instructions;

FIG. 7 is a schematic representation of an inventive desired trajectory on a work piece to be plasma treated; and

FIG. 8 is the representation of the inventive method for plasma treatment of workpieces, with reference to schematic timing diagrams for various operating parameters and control signals.

### DETAILED DESCRIPTION OF THE INVENTION

At the outset, it should be appreciated that like drawing numbers on different drawing views identify identical, or functionally similar, structural elements of the invention. While the present invention is described with respect to what is presently considered to be the preferred aspects, it is to be understood that the invention as claimed is not limited to the disclosed aspects. The illustrated embodiments are merely ways in which an inventive hand-held device or a method for plasma treatment of work-pieces is designed and the features disclosed are combined, respectively.

Furthermore, it is understood that this invention is not limited to the particular methodology, materials and modifications described and, as such, may, of course, vary. It is also understood that the terminology used herein is for the purpose of describing particular aspects only, and is not intended to limit the scope of the present invention, which is limited only by the appended claims.

Unless defined otherwise, all technical and scientific terms used herein have the same meaning as commonly understood to one of ordinary skill in the art to which this invention belongs. Although any methods, devices or materials similar or equivalent to those described herein can be used in the practice or testing of the invention, the preferred methods, devices, and materials are now described.

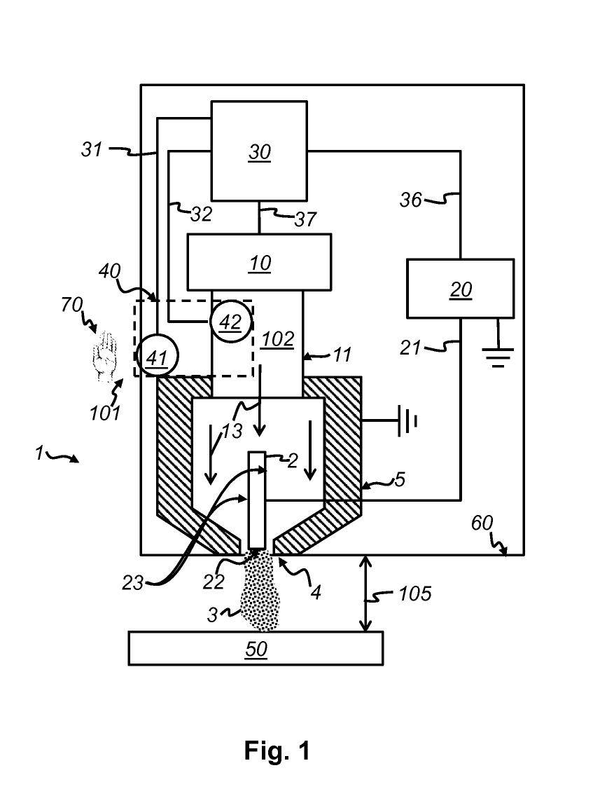

FIG. 1 shows a schematic view of an embodiment of the inventive hand-held device 1 for plasma treatment of workpieces 50. A housing 60 of the hand-held device 1 receives a plasma source 5, a gas supply unit 10 and a voltage source 20. The gas supply unit 10 is fluidly connected via a gas supply channel 11 with the plasma source 5. It is used for supplying a gas stream 13 to the plasma source 5 which flows over an electrode unit 2 of the plasma source 5. Simultaneously, the gas stream 13 is used for cooling the plasma source 5 in particular. The voltage source 20 is connected via at least one electrical lead 21 with the electrode unit 2. By applying a voltage to the electrode unit 2 a plasma stream 3 is ignited with the gas stream 13. Through an outlet nozzle 4 of the housing 60 the plasma stream 3 is directed to a workpiece 50.

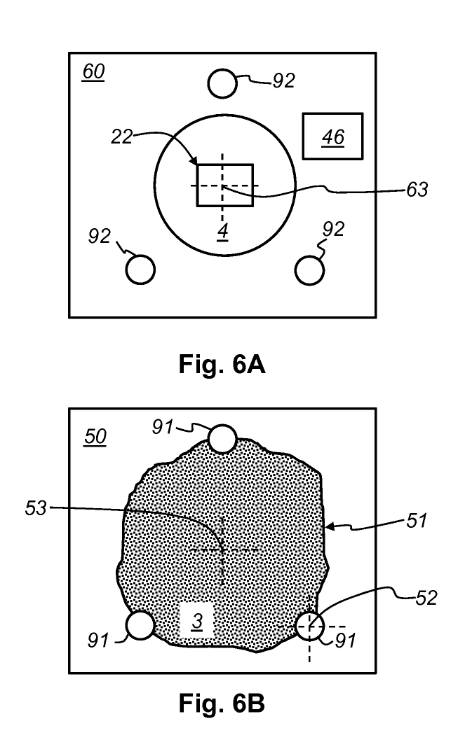

Preferably, the electrode unit 2 is a piezoelectric transducer. In this case two secondary sides of the electrode unit 2 connected via one electrical lead 21 each with the voltage source 2 (not shown). Because of the high transformation ratio with respect to the voltage amplitude, a high alternating voltage is achieved at a primary side 22 by mechanical oscillations of the piezoelectric transformer, wherein a low alternating voltage is applied to the secondary side, for example by a typical portable battery. The plasma stream 3 is ignited at the primary side 22 from the gas stream 13. Preferably, the primary side 22 of the electrode unit 2 is arranged contact free and centered in the outlet nozzle 4 (see FIG. 6A).

The hand-held device 1 comprises a sensor system 40 in order to determine operating parameters 100. The sensor system 40 has at least one operator sensor device 41 in order to determine a position 101 of the operator 70 with respect to the plasma source 5. The operator sensor device 41 serves especially the examination, if the plasma stream 3 is directed towards the operator 70. Furthermore, the sensor system 40 includes a pressure sensor 42 in order to determine a static and/or dynamic pressure 102 in the gas supply unit 10, the gas supply channel 11 or the plasma source 5. In case the gas stream 13 is composed of several gas components, the pressure sensors 42 can measure several selected partial pressures. A means 30 of the hand-held device 1 is communicatively coupled to the sensor system 40 via control data lines 31, 32, 36 in order for synchronized detection of the collected operating parameters 100. Additionally, the means 30 is communicatively coupled via control data lines 36, 37 to the voltage source 20 and the gas supply unit 10, respectively. The means 30 controls the voltage source 20, the gas supply unit 10 and a control loop, composed of voltage source 20, gas supply unit 10 and sensor system 40, respectively.

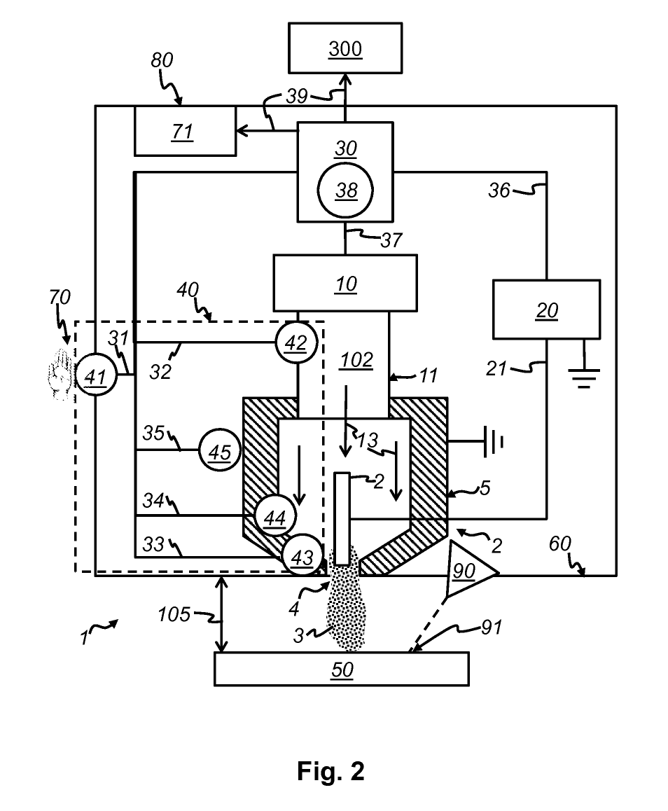

FIG. 2 shows a schematic view of a further embodiment of the inventive hand-held device 1. The hand-held device 1 has all the features of the embodiment of FIG. 1. In addition to the operator sensor device 41 and the pressure sensor 42, the sensor system 40 comprises, for example a flow sensor 43 associated to the outlet nozzle 4, for example a temperature sensor 44 in the plasma source 5 and several kinematic sensors 45. All sensors are connected via respective control data lines 31, 32, 33, 34, 35 with the means 30. The means 30 has an internal clock 38 so that it can control the voltage source 20 and the gas supply unit 10 in a temporally coordinated manner. According to that, the gas stream 13 flows through the plasma source 5 during a lead time prior to the release of the voltage source 20. This ensures that gas stream 13 is stabilized prior to the ignition of the plasma stream 3 therefrom. For safety reasons and for cooling after plasma treatment, the gas stream 13 may flow through the plasma source 5 during a stopping time after switching off the voltage source 20. The means 30 is connected also via further data lines 39 to an internal or external database 300 and/or a user display 71 for displaying operator notes 80. Further, the housing 60 carries a targeting device 90, which as well projects operator notes 80, like light signals 91, onto the workpiece 50.

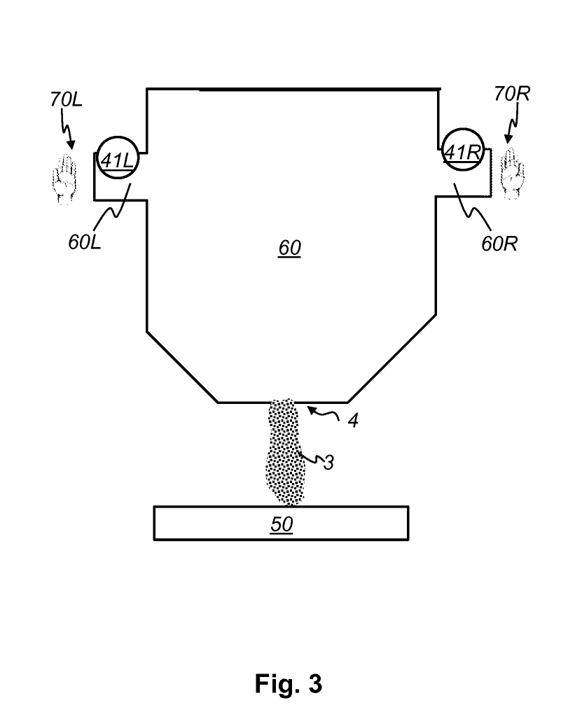

FIG. 3 shows a schematic view of an embodiment of a housing 60 of the inventive hand-held device 1. A left handle 60L and a right handle 60R are formed on the housing 60. The skilled person recognizes that the schematically shown embodiment of the handles 60L, 60R needs to be adapted to the ergonomic requirements of a hand-held device 1. The left handle 60L and the right handle 60R carry a left hand sensor 41L and a right hand sensor 41R respectively, which are triggered by the left hand 70L and the right hand 70R of the operator 70, respectively. When both hand sensors 41L, 41R are activated it is assured that the operator 70 holds the hand-held device 1 properly, and the plasma stream 3 exiting from the outlet nozzle 4 is directed substantially away from his body. The invention provides for performance reliability, that the means 30 releases the voltage source 20 only, as long as both hand sensors 41L, 41R remain triggered.

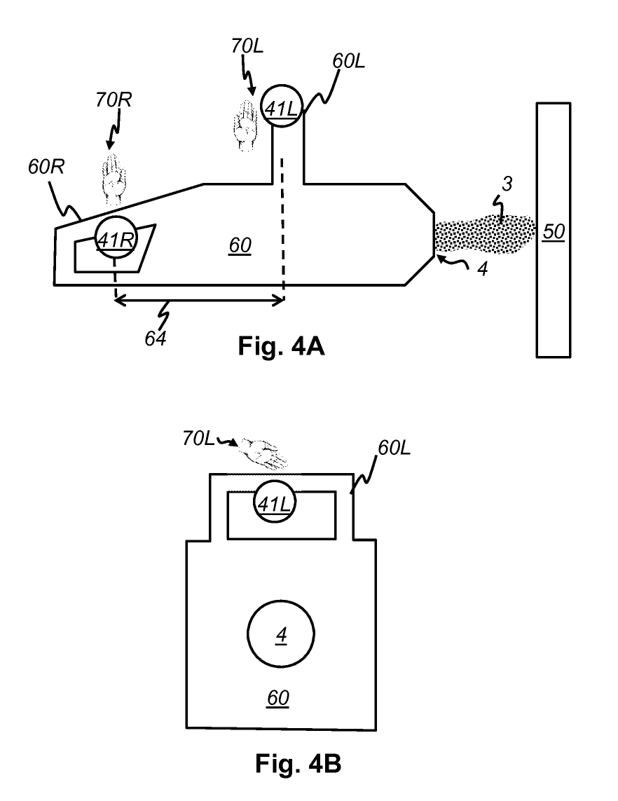

FIG. 4A shows a schematic view of another embodiment of the housing 60 of the inventive hand-held device 1. FIG. 4B shows another schematic view of the embodiment of the housing 60 of the inventive hand-held device 1 according to FIG. 4A. The basic form of housing 60 matches a chain saw. The handles 60L, 60R are in the form of a bow. The distance 64 between the handles is for safety reasons so dimensioned that both handles 60L, 60R cannot be triggered with one typical human hand simultaneously.

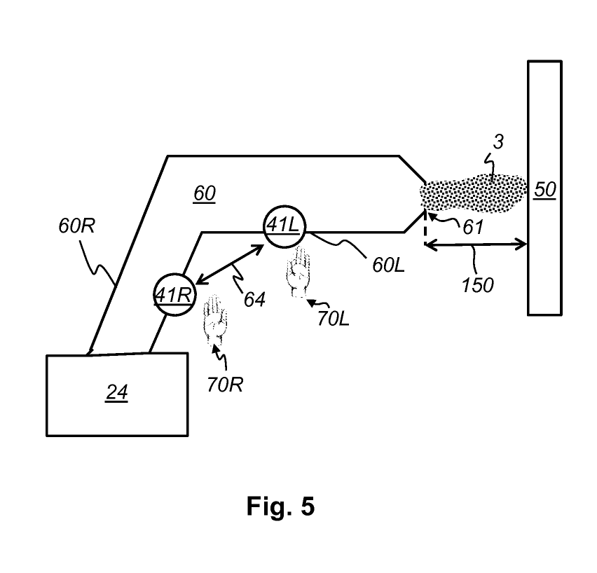

FIG. 5 shows a schematic view of another embodiment of the housing 60 of the inventive hand-held device 1. The basic form of the housing 60 corresponds to a drilling machine. The right hand sensor 41R also acts as a control element for inputting control signals by the operator 70. For example, it can be configured as an analog or digital push button or rotary knob. The stronger an operator 70 actuates it, the higher the means 30 controls for example the plasma power per unit area on the workpiece 50. The means 30 provokes the increase in the plasma power by the combined control of the voltage source 20 and gas supply unit 10. In this case, the left hand sensor 41L is for example a push button or capacitive sensor, which exclusively detects the left hand 70L position 101 of an operator 70. In addition, the hand sensor 41L can serve also as the operator display 71. For example, he can light up continuously by means of an integrated light source (not shown) when the hand-held device 1 is ready for operation. He blinks, when the operational readiness is not yet or no longer available or one of the operating parameters 100 is longer above or below a lower threshold 102L or upper threshold 102U as it is tolerable for the operational readiness. The operator 70 or the manufacturer of the hand-held device 1 can set, depending on the application, how long such a deviation is tolerable. The maximum tolerable duration of the deviation, can be programmed to the means 30 in the form of time intervals Δt101 and Δt102 respectively. It is also conceivable that it is implemented by a smoothing algorithm (like a Fourier transformation) in the means 30. In order to provide a technically competent operator 70 with more direct influence on the plasma intensity and plasma condition, it is also conceivable to design the right hand sensor 41R as a control element for adjusting the voltage and the left hand sensor 41L as a control element for adjusting the gas stream 13.

Preferably in or on the housing 60, a battery 24 is provided which feeds the clamp-voltage source 20. In this embodiment, the hand-held device is not connected with cables and/or tubing. It can also be a power supply (not shown), which is provided in the housing 60 with a common power plug (not shown).

FIG. 6A is a schematic view of the hand-held device 1, wherein the targeting device 90 is shown. The targeting device 90 includes, for example, three or more projectors 92, e.g., homogeneously distributed angularly around the output nozzle 4 for the plasma jet 3. Each projector 92 projects at least a light signal 91 on the workpiece 50, as shown in FIG. 6B. In the embodiment shown, the light signals are point-like. Other shapes are also conceivable, such as lines, arrows or other symbols. The light signals shown in FIG. 6B mark an area 51 on the workpiece 50, to which the plasma beam 3 is effectively applied. The plasma treatment takes place or is going to take place under the desired operating conditions, if the plasma has not yet been ignited. In the simplest case, a single projector 92, configured for example as a laser pointer, could mark a location 52 which is located in the center 53 of the area 51 to be swept with the plasma. The center 53 of the area 51 to be swept with plasma is located vertically below the center of the outlet nozzle 4 and the primary side 22 of the electrode unit 2 respectively. The marking of the center 53, however, requires that the projector 92 is arranged at an angle other than the angle the outlet nozzle 4 is directed to the workpiece 50. The marked location 52 shifts depending on the working distance 105 and can thus be distorted depending on the working distance 105. An advantage of the embodiment targeting device 90 shown in FIG. 6A is that the projectors 92 may be directed at the same angle as the outlet nozzle 4 toward the workpiece 50 so that the marked location 52 does not depend on the operating distance 105. Moreover, typical working distances 105 between the outlet nozzle 4 and the workpiece 50 are only 8-12 mm (see FIG. 1). Due to such a short working distances, the center of the area 51 to be swept with plasma may be obscured for an operator 70 by the housing 60 of the hand-held device 1. An off-center marked area 51 illustrated as in FIG. 6B, is more visible. Further, in addition to the outlet nozzle 4, a camera 46 may be disposed in the housing 60 in order to take-up an image the workpiece 50 and to transmit the image data to the means 30. The means 30 can apply to this image data an image recognition process in order to identify the workpieces 50 and certain structures on workpieces 50. In the same way, the means 30 can evaluate the distance- and angle-dependent shape and relative position of the light signals in order to determine the position, the working distance 105 and/or the angular orientation of hand-held device 1 relative to the workpiece 50.

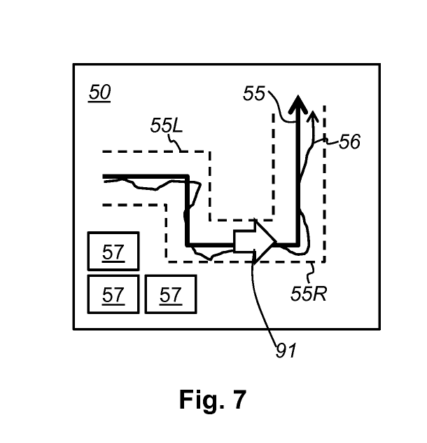

FIG. 7 shows a schematic representation of an inventive labeled and to be plasma treated desired trajectory 55 on a workpiece 50. A desired trajectory 55 can be defined in the means 30 by time dependent target intervals of kinematic operating parameters 100 on the workpiece 50. These kinematic operating parameters 100 represent, in particular, the working distance 105. The operator 70 (see FIGS. 1 and 2) guides the hand-held unit 1 on an actual trajectory 56 along the desired trajectory 55 through the workpiece 50 the profile of the reference trajectory 55 above the workpiece 50. An operator 70, for example, can learn from the reference marks 57 on the workpiece 50 the run of the desired trajectory 55 and the means 30 evaluates from the captured image data from the camera 46 the desired trajectory 55 respectively. Furthermore, the means 30 evaluates the actual trajectory 56 and their deviation from the desired trajectory 55. By means of the targeting device 90, the target trajectory 55 is projected at least in sections onto the workpiece 50. In FIG. 7, for example, the light signal 91 is projected in the form of an arrow in a local feed direction of the workpiece 50. By modulating the form of the arrow or by a flashing arrow other user notes 80 can be displayed besides the kinematic operating parameter 100 then the feed rate. It is also conceivable that the image data captured by the camera 46 are continuously displayed on a user display 71 configured as a screen. It is also conceivable that the means 30 shows on a user display 71, the actual trajectory 56, the desired trajectory 55, the center 53 of the current location 52 to be plasma treated and/or other operator notes 80 in an overlapped manner. Similarly, the course of a left desired trajectory 55L and a right desired trajectory 55R can be recorded and displayed. This has the advantage that an operator 70 can see all information necessary for the plasma treatment in well arranged and linked form on the operator display 71. Light signals 91, projected on the workpiece 50, can be concealed by the housing 60 and are overlain by the luminosity of the plasma stream 3.

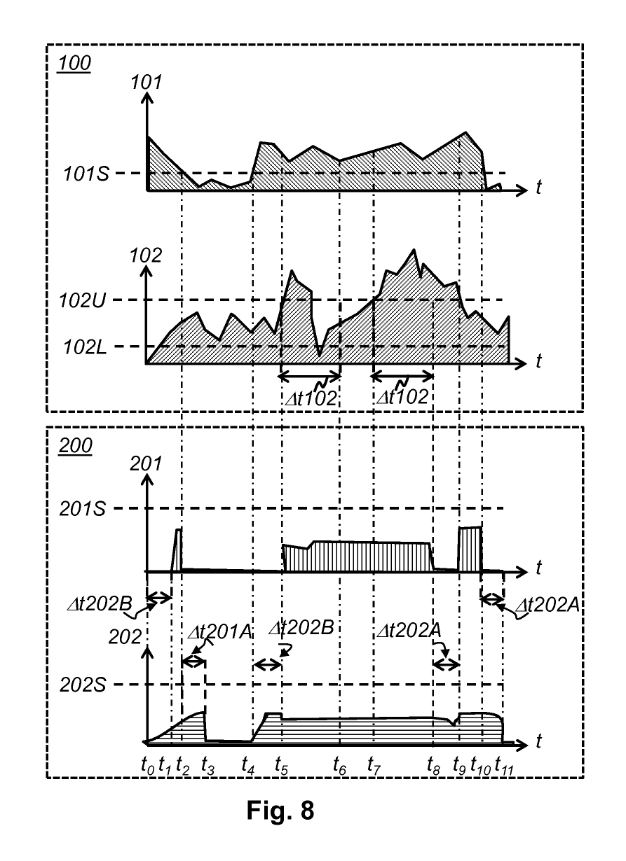

In FIG. 8, an inventive method is shown for the plasma treatment of workpieces 50 with reference to schematic timing diagrams for various operating parameter 100 and control parameters 200. The exemplified operating parameters 100 are: a position 101 of an operator 70 relative to the plasma source 5 and a pressure 102 in the plasma source 5. The exemplified shown control parameters 200 are: a control signal 201 for the voltage source 20 and the control signal 202 for the gas supply unit 10. The detection of the operating parameters 100, and the output of control parameters 200 is performed synchronized so that the points in time t₀, . . . , t₁₁ refer to all timing diagrams.

At time t₀ an operator 70 actuates an operator sensor device 41 of inventive hand-held device 1. The operator sensor device 41 transmits the operating parameter 100 “position 101” to the means 30 and notes that its signal strength is above a predetermined lower position threshold 101S. Then, it outputs a control signal 202 to the gas supply unit 10, which causes the startup of the gas stream 13.

At the time t₁, after a lead time Δt202B for the stabilization of the gas stream 13, the means 30 determines that the pressure 102 is within a target interval defined by a lower pressure threshold value 102L and the upper pressure threshold value 102U. Then, it outputs a control signal 201 to the voltage source 20, which for example is proportional to the voltage applied to the electrode unit 2.

At time t₂, the operator 70 loosens his grip around a user sensing means 41 so that the operating parameter 100 “position 101” falls below the lower position threshold 101S. Immediately, due to safety reasons, the means 30 stops the control signal 201 to the voltage source 20 and thus the voltage, so that the plasma stream 3 is extinguished.

At time t₃, after a stopping time Δt202A, the means 30 stops the control signal 202 for the gas stream 13. The overtravel of the gas stream 13 cools the plasma source 5.

At time t₄, the operator 70 correctly touches the hand-held device 1 again so that the operating parameter 100 “position 101’ again exceeds lower position threshold 101S. Then the means 30 firstly releases the gas stream 13. After a new lead time Δt202B, at time t₅, the voltage is free again, so that again a plasma stream 3 is generated.

Between time t₅ and t₆ there are short-term pressure 102 fluctuations, which are defined as tolerable because they do not leave the target interval longer than a preset time interval Δt102. The means 30 does not change the control signals 201, 202 for the voltage source 20 and the gas supply unit 10.

Between time t₇ and the time t₉, the pressure 102 exceeds the upper pressure threshold 102U longer than the interval Δt102. At time t₈ the means 30 stops the control signal 201 for the voltage source 20. The control signal 202 for the gas supply unit 10 would be stopped as well after an expiration of a stopping time Δt202A, if at the time t₉, the pressure 102 is not back within the target interval. In the present example, the gas stream 13 thus proceeds. At the time t₉, the voltage source 20 is again activated so as to ignite a plasma stream 3.

At the time t₁₀, the operator 70 stops the plasma treatment and puts down the hand-held device 1. The means 30 interrupts the control signal 201 for the voltage source 20 and interrupts immediately at the time t₁₁, after a new stopping time Δt202A, the control signal 202 for the gas supply unit 10.

The process may be analogous with each combination of operating parameters 100. Likewise control thresholds 201S and 202S can be defined for the control signals 201 and 202, wherein the means 30 turns off the voltage source 20 and possibly the gas supply unit 10.

Thus, it is seen that the objects of the present invention are efficiently obtained, although modifications and changes to the invention should be readily apparent to those having ordinary skill in the art, which modifications are intended to be within the spirit and scope of the invention as claimed. It also is understood that the foregoing description is illustrative of the present invention and should not be considered as limiting. Therefore, other embodiments of the present invention are possible without departing from the spirit and scope of the present invention.

### LIST OF REFERENCE NUMERALS

1 hand-held device
2 electrode unit
3 plasma stream
4 outlet nozzle
5 plasma source
10 gas supply unit
11 gas supply channel
13 gas stream
20 voltage source
21 electrical lead
22 primary side
24 battery
30 means
31 control data line
32 control data line
33 control data line
36 control data line
37 control data line
38 internal clock
39 data line
40 sensor system
41 operator sensor device
41L left hand sensor
41R right hand sensor
42 pressure sensor
43 flow sensor
44 temperature sensor
45 kinematic sensors
50 workpiece
51 area
52 location
53 center
55 desired trajectory
55L left desired trajectory
55R right desired trajectory
56 actual trajectory
60 housing
60L left handle
60R right handle
64 distance
70 operator
70L left hand
70R right hand
71 user display
80 operator notes
90 targeting device
91 light signal
92 projector
100 operating parameter
101 position
101S lower position threshold
102 pressure
102L lower threshold
102U upper threshold
105 working distance
200 control parameter
201 control signal
201S control threshold
202 control signal
202S control threshold
300 database
Δt202A stopping time
Δt202B lead time

What is claimed is:

1. A hand-held device for the plasma treatment of workpieces, comprising:
a housing for containing a plasma source;
a gas supply unit for supplying a gas stream to the plasma source;
a voltage source, being connected via at least one electrical lead with an electrode unit of the plasma source for generating a plasma stream;
an outlet nozzle of the housing from which the plasma stream can be directed to a workpiece;
a sensor system for the collection of operating parameters, the sensor system comprising:
at least one operator sensor device including a left hand sensor and a right hand sensor to levy a position of a right hand and a left hand of an operator on the housing, and thereby a position of the operator is detectable with respect to the plasma source; and
at least one pressure sensor for imposing a pressure in the gas supply unit; and
a means which is communicatively coupled to the sensor system for synchronized detection of the collected operating parameters and to at least to the voltage source for its control via control data lines.

2. The hand-held device recited in claim 1, wherein the sensor system additionally comprises at least one of the following sensors:
a flow sensor is arranged in the plasma source for collecting a flow rate of the gas stream through the plasma source;
a temperature sensor is arranged in or at the plasma source for collecting a temperature of the plasma source;
a camera for detecting at least a portion of the workpiece; or
a kinematic sensor for collecting at least a kinematic factor of the hand-held device relative to the workpiece.

3. The hand-held device recited in claim 1, wherein the sensor system additionally comprises at least one of the following sensors:
a flow sensor is arranged in the gas supply unit for collecting a flow rate of the gas stream through the plasma source;
a temperature sensor is arranged in or at the plasma source for collecting a temperature of the plasma source;
a camera for detecting at least a portion of the workpiece; or
a kinematic sensor for collecting at least a kinematic factor of the hand-held device relative to the workpiece.

4. The hand-held device recited in claim 1, wherein the means is constructed for performing each of a set-actual comparison of each of the operating parameters collected by the sensor system.

5. The hand-held device recited in claim 1, wherein the sensor system is constructed for performing each of a set-actual comparison of each of the operating parameters collected by the sensor system.

6. The hand-held device recited in claim 1, wherein the hand-held device has a targeting device for marking a region on the workpiece to which the plasma stream is directed.

7. The hand-held device recited in claim 6, wherein the targeting device comprises at least one projector to project at least one light signal onto the workpiece.

8. The hand-held device recited in claim 7, wherein the light signals are modulated with respect to time, color and/or form by means of the at least one projector.

9. The hand-held device recited in claim 1, wherein at least one operator display of the hand-held device is used for outputting optical, acoustic and/or vibratory user information with regard to the operational state of the hand-held device.

10. The hand-held device recited in claim 1, wherein the means have a database for storage of operating parameters and/or of metadata derived from operating parameters and/or related the user.

11. The hand-held device recited in claim 1, wherein the means is communicatively connected to the gas supply unit via a control data line for regulating the gas stream and wherein the gas supply unit is a controllable blower and/or a gas bottle with a controllable valve.

12. A method for plasma treatment of workpieces, comprising the following steps:
generating with a plasma source of a hand-held device a plasma stream for the plasma treatment;
directing the generated plasma stream to a workpiece;
collecting with a sensor system at least two operating parameters, wherein with at least at least one operator sensor device with a left hand sensor and a right hand sensor detect a position of an operator relative to the plasma source, and with at least one pressure sensor of the sensor system, a pressure in a gas supply unit of the plasma source is detected;
synchronizing the collected operating parameters with a means; and
generating control signals by the means, which are based on the collected operating parameters for unblocking and/or controlling at least a voltage source of the plasma source.

13. The method of claim 12, wherein by means of the sensor system additionally at least one of the following operating parameters are collected:
a flow rate of the gas stream by means of at least one flow sensor arranged in the plasma source;
a temperature of the plasma source by means of at least one temperature sensor arranged in or at the plasma source;
an optical image of at least a portion of the workpiece by means of a camera of the hand-held device; or
a kinematic operating parameter of the hand-held device relative to the workpiece by means of at least one kinematic sensor arranged at the hand-held device.

14. The method of claim 12, wherein by means of the sensor system additionally at least one of the following operating parameters are collected:
a flow rate of the gas stream by means of at least one flow sensor arranged in the gas supply unit;
a temperature of the plasma source by means of at least one temperature sensor arranged in or at the plasma source;
an optical image of at least a portion of the workpiece by means of a camera of the hand-held device; or
a kinematic operating parameter of the hand-held device relative to the workpiece by means of at least one kinematic sensor arranged at the hand-held device.

15. The method of claim 12, wherein a set-actual comparison is carried out on the collected operating parameters, and wherein the means generates control signals if the desired operating parameter of the respective actual comparison is longer than a respective time interval above a respective threshold value.

16. The method of claim 12, wherein a set-actual comparison is carried out on the collected operating parameters, and wherein the means generates control signals if the desired operating parameter of the respective actual comparison is longer than a respective time interval below a respective threshold value.

17. The method of claim 12, wherein a set-actual comparison is carried out on the collected operating parameters, and wherein the means generates control signals if the desired operating parameter of the respective actual comparison is longer than a respective time interval outside of a respective set interval, which is defined by a respective upper threshold and a respective lower threshold.

18. The method of claim 12, wherein a set-actual comparison is carried out on the collected operating parameters, and wherein the means generates control signals if the desired operating parameter of the respective actual comparison is longer than a respective time interval outside of a respective set interval, which is defined by a respective upper threshold and a respective lower threshold.

19. The method of claim 12, wherein by means of an operator display of the hand-held device, user information relating to a operational state of the hand-held device, at least one derived operating parameter exceeding the upper threshold of at least one of the collected operating parameters are displayed to the operator.

20. The method of claim 12, wherein by means of an operator display of the hand-held device, user information relating to a operational state of the hand-held device, at least one derived operating parameter underrun of the lower threshold of at least one of the collected operating parameters are displayed to the operator.

21. The method of claim 12, wherein at least one light signal is projected to a select area on the workpiece to which the plasma stream is directed by means of a targeting device with at least one projector of the hand-held device to the workpiece.

22. The method of claim 13, wherein a reference trajectory is defined on the workpiece by time-dependent target intervals of kinematic operating parameters, wherein the operator guides the hand-held device on an actual trajectory along the reference trajectory over the workpiece and wherein the targeting device projects the reference trajectory at least in sections onto the workpiece.

23. The method of claim 14, wherein a reference trajectory is defined on the workpiece by time-dependent target intervals of kinematic operating parameters, wherein the operator guides the hand-held device on an actual trajectory along the reference trajectory over the workpiece and wherein the targeting device projects the reference trajectory at least in sections onto the workpiece.

24. The method of claim 12, wherein the means only outputs the control signals to the voltage source as long as none of the derived operating parameters are longer than a respective time interval outside a respective target interval exceed a respective maximum threshold value.

25. The method of claim 12, wherein the means only outputs the control signals to the voltage source as long as none of the derived operating parameters are longer than a respective time interval outside a respective target interval underrun a respective minimum threshold value.

26. The method of claim 12, wherein the means generates control signals for a gas supply unit of the plasma source and controls the voltage source and the gas supply unit as a function of the prevailing operating parameters of the gas supply unit and the voltage source.

27. The method of claim 12, wherein the means temporally coordinated control the voltage source and the gas supply unit by means of an internal clock such that the gas stream flows through the plasma source during a lead time prior to clearance of the voltage source and/or during a stopping time after switching off the voltage source.

28. The method of claim 12, wherein the operating parameters and/or derived operating parameters and/or the operator related metadata are stored in a database which is communicatively coupled to the means.

29. A hand-held device for the plasma treatment of workpieces, comprising:
a housing for containing a plasma source;
a gas supply unit for supplying a gas stream to the plasma source;
a voltage source, being connected via at least one electrical wire with an electrode unit of the plasma source for generating a plasma stream;
an outlet nozzle of the housing from which the plasma stream can be directed to a workpiece;
a sensor system for the collection of operating parameters, wherein the sensor system has a operator sensor device, at least one pressure sensor, at least one flow sensor, at least one temperature sensor, at least one camera and/or at least one kinematic sensor; and
a means which is communicatively coupled to the sensor system for synchronized detection of the collected operating parameters and to at least to the voltage source for its control via data lines.

30. The hand-held device recited in claim 29, wherein the operator sensor device is equipped with a left hand sensor and a right hand sensor to levy a position of a right hand and a left hand of an operator on the housing, and thereby a position of the operator is detectable with respect to the plasma source.

31. The hand-held device recited in claim 29, wherein the at least one pressure sensor is used for imposing a pressure in the gas supply unit.

32. The hand-held device recited in claim 29, wherein the at least one flow sensor is arranged in the plasma source for collecting a flow rate of the gas stream through the plasma source.

33. The hand-held device recited in claim 29, wherein the at least one flow sensor is arranged in the gas supply unit for collecting a flow rate of the gas stream through the plasma source.

34. The hand-held device recited in claim 29, wherein the at least one temperature sensor is arranged in or at the plasma source for collecting a temperature of the plasma source.

35. The hand-held device recited in claim 29, wherein the at least one camera is arranged for detecting at least a portion of the workpiece.

36. The hand-held device recited in claim 29, wherein the at least one kinematic sensor is arranged for collecting at least a kinematic factor of the hand-held device relative to the workpiece.
